(19) United States
(12) Patent Application Publication
(10) Pub. No.: US 2026/0045766 A1
(43) Pub. Date: Feb. 12, 2026

(54) Evaluation Method, Device And Program For Semiconductor Laser

(71) Applicant: Nippon Telegraph and Telephone Corporation, Tokyo (JP)

(72) Inventors: Koji Takeda, Musashino-shi, Tokyo (JP); Yoshiho Maeda, Musashino-shi, Tokyo (JP)

(21) Appl. No.: 18/850,478

(22) PCT Filed: Apr. 1, 2022
(86) PCT No.: PCT/JP2022/016991

§ 371 Date: Apr. 4, 2025

(51) Int. Cl. H01S 5/068; H01S 5/00; H01S 5/06

(52) U.S. Cl. CPC H01S 5/06812; H01S 5/0014; H01S 5/0617

(57) ABSTRACT

A semiconductor laser evaluation method of the present invention acquires an intersection point between an approximate straight line acquired by a linear approximation for a predetermined measurement point and an X-axis, in a current-light output characteristic which represents, as a relationship between an injection current of the semiconductor laser and an optical output of the semiconductor laser, the injection current on the X-axis and the optical output on a Y-axis, and determines a minimum value of local maximum values of the intersection points obtained by shifting the measurement point, as a threshold current of the semiconductor laser. Thus, the present invention can provide a semiconductor laser evaluation method capable of accurately evaluating the threshold current of a semiconductor laser.

### TECHNICAL FIELD

The present invention relates to a semiconductor laser evaluation method, device and program for evaluating a threshold current of a semiconductor laser.

### BACKGROUND ART

In research and development of semiconductor lasers, it is necessary to evaluate and feed-back the characteristics of various semiconductor lasers to a design. As an important parameter of semiconductor laser characteristics, there is an injection current at which laser oscillation starts, i.e., a threshold current. Typically, the threshold current is obtained from the characteristics (I-L characteristics) of the optical output obtained when the current is experimentally injected into the semiconductor laser. In the related art, the following method has been used for evaluating the threshold current (for example, NPL 1).
(1) In the I-L characteristics, a threshold current is acquired from an intersection point between a straight line passing through two measurement points (I-L characteristics data) corresponding to different optical outputs P1 and P2 after laser oscillation and an X-axis (hereinafter referred to as “conventional method 1”).
(2) A threshold current is acquired from an intersection point between a straight line passing through two measurement points (I-L characteristic data) corresponding to optical outputs P3 and P4 lower than the optical output in the threshold current acquired by the conventional method 1 and a straight line in the conventional method 1 (hereinafter referred to as “conventional method 2”).
(3) A differential coefficient dL/dI is obtained at each of measurement points of the I-L characteristic, and a threshold current is acquired from a current corresponding to a half value of a peak value of dL/dI (hereinafter referred to as “conventional method 3”).
(4) A second-order differential coefficient d²L/dI² is obtained at each measurement point of the I-L characteristic, and a threshold current is acquired from a current corresponding to a peak value of d²L/dI² (hereinafter referred to as “conventional method 4”).

Further, a method for evaluating a threshold current based on a relaxation oscillation frequency is disclosed in NPL 2.

### CITATION LIST

### Non Patent Literature

[NPL 1] “The Differences Between Threshold current Calculation Methods, ” Newport Application Notehttps: //www. newport. com. cn/medias/sys_master/images/images/hc9/hd1/9680121757726/AN-12-REV03-Differences-Between-Threshold-Current-Calculations. pdf

[NPL 2] D. M. Kane and Joshua P. Toomey, “Precision Threshold current Measurement for Semiconductor Lasers Based on Relaxation Oscillation Frequency,” Journal of Lightwave Technology, Vol. 27, No. 15, pp. 2949-2953 (2009).

### SUMMARY OF INVENTION

### Technical Problem

However, in the above-described conventional method, it was difficult to accurately evaluate the threshold current by using the same algorithm and the same parameter, when a plurality of semiconductor lasers having greatly different optical outputs are evaluated or when I-L characteristics in the vicinity of the threshold are different from those in a normal form.

Therefore, when semiconductor lasers having various characteristics are collectively evaluated by using the same algorithm or the same parameter, it was necessary to separately confirm whether the threshold current was accurately evaluated by drawing a graph of I-L characteristics after the evaluation.

### Solution to Problem

In order to solve the above problem, a semiconductor laser evaluation method according to the present invention comprises, in a current-light characteristic representing a relationship between an injection current of a semiconductor laser and an optical output of the semiconductor laser, with the injection current on an X-axis and the optical output on a Y-axis, obtaining an intersection point between an approximate straight line acquired by a linear approximation for a predetermined measurement point and the X-axis; and determining a minimum value of local maximum values of the intersection point obtained by shifting the measurement point, as a threshold current of the semiconductor laser.

A semiconductor laser evaluation method according to the present invention includes a step of acquiring a current-light output characteristic which represents, as a relationship between an injection current of a semiconductor laser and an optical output of the semiconductor laser, the injection current on an X-axis and the optical output on a Y-axis; a step of acquiring an approximate straight line by a linear approximation for a predetermined measurement point in the current-light output characteristic; a step of obtaining an intersection point between the approximate straight line and the X-axis; a step of shifting the measurement point to obtain local maximum values of the intersection point; and a step of determining a minimum value of the local maximum values as a threshold current of the semiconductor laser.

A semiconductor laser evaluation method according to the present invention acquires an intersection point between an approximate straight line acquired by a linear approximation for a predetermined measurement point and an X-axis, in a current-light output characteristic which represents, as a relationship between an injection current of the semiconductor laser and an optical output of the semiconductor laser, the injection current on the X-axis and the optical output on a Y-axis; acquires local maximum values of the intersection points by shifting the measurement point; acquires another approximate straight line by a linear approximation with respect to a predetermined other measurement point between an origin of the X-axis and a minimum value of the local maximum values; and determines a current value corresponding to an intersection point between the approximate straight line and the other approximate straight line as a threshold current of the semiconductor laser.

A semiconductor laser evaluation method according to the present invention includes a step of acquiring a current-light output characteristic which represents, as a relationship between an injection current of a semiconductor laser and an optical output of the semiconductor laser, the injection current on an X-axis and the optical output on a Y-axis; a step of acquiring an approximate straight line by a linear approximation for a predetermined measurement point in the current-light output characteristic; a step of obtaining an intersection point between the approximate straight line and the X-axis; a step of shifting the measurement point to obtain local maximum values of the intersection points; a step of acquiring another approximate straight line by the linear approximation for a predetermined other measurement point in a region between an origin of the X-axis and a minimum value of the local maximum values; and a step of determining a current value corresponding to the intersection point between the approximate straight line and the other approximate straight line, as a threshold current of the semiconductor laser.

A semiconductor laser evaluation device according to the present invention includes a drive unit which supplies an injection current to a semiconductor laser; a detection unit which detects an optical output of the semiconductor laser; and a calculation unit which acquires an intersection point between an approximate straight line acquired by a linear approximation for a predetermined measurement point and an X-axis, in a current-light output characteristic which represents, as a relationship between an injection current of the semiconductor laser and an optical output of the semiconductor laser, the injection current on the X-axis and the optical output on a Y-axis, and determines a minimum value of local maximum values of the intersection points obtained by shifting the measurement point, as a threshold current of the semiconductor laser.

A semiconductor laser evaluation device according to the present invention includes a drive unit which supplies an injection current to a semiconductor laser; a detection unit which detects an optical output of the semiconductor laser; and a calculation unit which acquires an intersection point between an approximate straight line acquired by a linear approximation for a predetermined measurement point and an X-axis, in a current-light output characteristic which represents, as a relationship between an injection current of the semiconductor laser and an optical output of the semiconductor laser, the injection current on the X-axis and the optical output on a Y-axis, acquires local maximum values of the intersection point by shifting the measurement point, acquires another approximate straight line by a linear approximation with respect to a predetermined other measurement point between an origin of the X-axis and a minimum value of the local maximum values, and determines a current value corresponding to an intersection point between the approximate straight line and the other approximate straight line, as a threshold current of the semiconductor laser.

A semiconductor laser evaluation program according to the present invention causes a computer to execute a process of obtaining an intersection point between an approximate straight line acquired by a linear approximation for a predetermined measurement point and an X-axis, in a current-light output characteristic which represents, as a relationship between an injection current of the semiconductor laser and an optical output of the semiconductor laser, the injection current on the X-axis and the optical output on a Y-axis, and determining a minimum value of local maximum values of the intersection points obtained by shifting the measurement point, as a threshold current of the semiconductor laser.

A semiconductor laser evaluation program according to the present invention causes a computer to execute a process of obtaining an intersection point between an approximate straight line acquired by a linear approximation for a predetermined measurement point and an X-axis, in a current-light output characteristic which represents, as a relationship between an injection current of the semiconductor laser and an optical output of the semiconductor laser, the injection current on the X-axis and the optical output on a Y-axis, acquiring local maximum values of the intersection points by shifting the measurement point, acquiring another approximate straight line by a linear approximation with respect to a predetermined other measurement point between an origin of the X-axis and a minimum value of the local maximum values, and determining a current value corresponding to an intersection point between the approximate straight line and the another approximate straight line as a threshold current of the semiconductor laser.

### Advantageous Effects of Invention

According to the present invention, it is possible to provide a semiconductor laser evaluation method, device and program capable of accurately evaluating the threshold current of a semiconductor laser.

### BRIEF DESCRIPTION OF DRAWINGS

FIG. 1 is a block diagram showing the configuration of a semiconductor laser evaluation device according to a first embodiment of the present invention.

FIG. 2A is a diagram for explaining the concept of a semiconductor laser evaluation method according to the first embodiment of the present invention.

FIG. 2B is a diagram for explaining the concept of the semiconductor laser evaluation method according to the first embodiment of the present invention.

FIG. 2C is a diagram for explaining the concept of the semiconductor laser evaluation method according to the first embodiment of the present invention.

FIG. 2D is a diagram for explaining the concept of the semiconductor laser evaluation method according to the first embodiment of the present invention.

FIG. 2E is a diagram for explaining the concept of the semiconductor laser evaluation method according to the first embodiment of the present invention.

FIG. 2F is a diagram for explaining the concept of the semiconductor laser evaluation method according to the first embodiment of the present invention.

FIG. 3 is a flowchart for explaining the semiconductor laser evaluation method according to the first embodiment of the present invention.

FIG. 4 is a diagram for explaining the effects of the semiconductor laser evaluation method according to the first embodiment of the present invention.

FIG. 5A is a diagram for explaining the effects of the semiconductor laser evaluation method according to the first embodiment of the present invention.

FIG. 5B is a diagram for explaining the effects of the semiconductor laser evaluation method according to the first embodiment of the present invention.

FIG. 5C is a diagram for explaining the effects of the semiconductor laser evaluation method according to the first embodiment of the present invention.

FIG. 6A is a diagram for explaining the effects of the semiconductor laser evaluation method according to the first embodiment of the present invention.

FIG. 6B is a diagram for explaining the effects of the semiconductor laser evaluation method according to the first embodiment of the present invention.

FIG. 7A is a diagram for explaining the effects of the semiconductor laser evaluation method according to the first embodiment of the present invention.

FIG. 7B is a diagram for explaining the effects of the semiconductor laser evaluation method according to the first embodiment of the present invention.

FIG. 7C is a diagram for explaining the effects of the semiconductor laser evaluation method according to the first embodiment of the present invention.

FIG. 8A is a diagram for explaining the effects of the semiconductor laser evaluation method according to the first embodiment of the present invention.

FIG. 8B is a diagram for explaining the effects of the semiconductor laser evaluation method according to the first embodiment of the present invention.

FIG. 9A is a diagram for explaining the concept of a semiconductor laser evaluation method according to a second embodiment of the present invention.

FIG. 9B is a diagram for explaining the concept of a semiconductor laser evaluation method according to a second embodiment of the present invention.

FIG. 9C is a diagram for explaining the concept of the semiconductor laser evaluation method according to the second embodiment of the present invention.

FIG. 10 is a flowchart for explaining the semiconductor laser evaluation method according to the second embodiment of the present invention.

FIG. 11A is a diagram for explaining the effects of the semiconductor laser evaluation method according to the second embodiment of the present invention.

FIG. 11B is a diagram for explaining the effects of the semiconductor laser evaluation method according to the second embodiment of the present invention.

FIG. 12 is a diagram showing a configuration example of a computer according to embodiments of the present invention.

### DESCRIPTION OF EMBODIMENTS

### First Embodiment

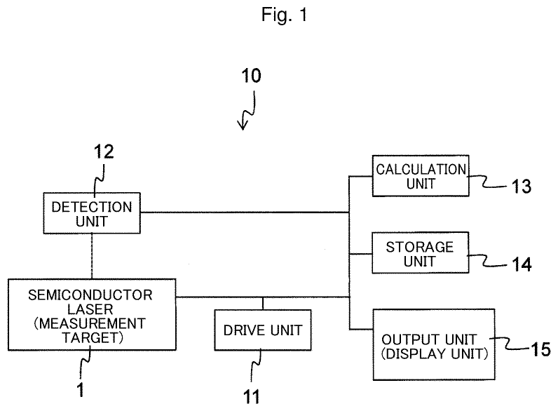

A semiconductor laser evaluation device, method, and program according to a first embodiment of the present invention will be described with reference to FIGS. 1 to 8B.

### Configuration of Semiconductor Laser Evaluation Device

As shown in FIG. 1, a semiconductor laser evaluation device 10 according to the present embodiment includes a drive unit 11, a detection unit 12, a calculation unit 13, a storage unit 14 and an output unit (display unit) 15.

The drive unit 11 injects a current into the semiconductor laser 1 to be measured.

The detection unit 12 receives the laser beam from the semiconductor laser 1 and measures the optical output.

The storage unit 14 stores a relation between an injection current value by the drive unit 11 and a light output value by the detection unit 12 as current-light (I-L) characteristics.

The calculation unit 13 reads the I-L characteristic data from the storage unit 14 and evaluates the threshold current based on the I-L characteristic data (to be described later). Here, the threshold current may be directly evaluated from the measured I-L characteristic data without reading the I-L characteristic data from the storage unit 14.

The output unit (display unit) 15 outputs (displays) I-L characteristic data, threshold current, etc.

### Semiconductor Laser Evaluation Method

First, the concept of the semiconductor laser evaluation method according to the present embodiment will be explained.

In the semiconductor laser evaluation method according to the present embodiment, the threshold current is evaluated on the basis of I-L characteristics representing the injection current of the semiconductor laser and the optical output of the semiconductor laser on an X-axis and a Y-axis, respectively.

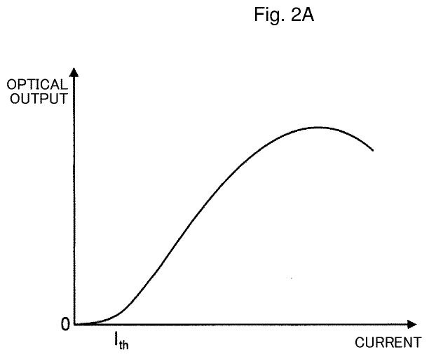

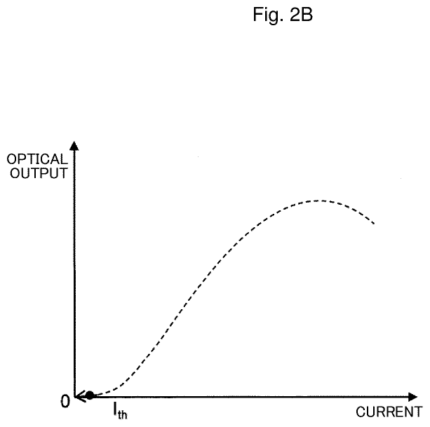

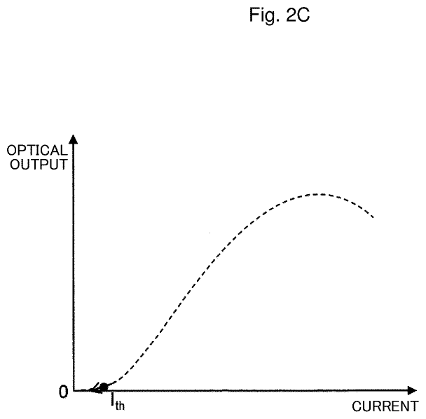

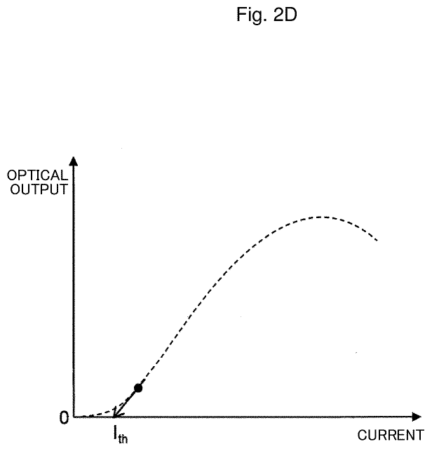

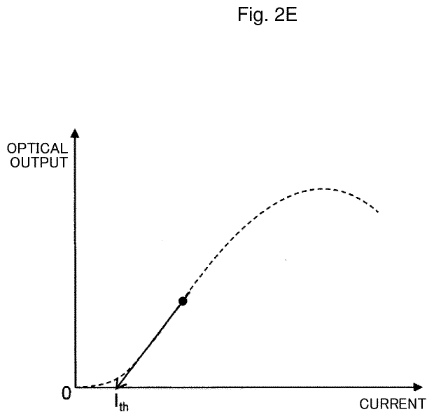

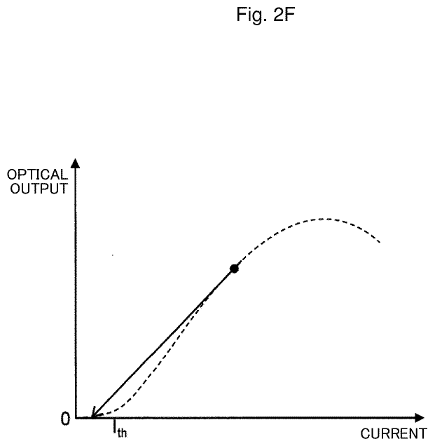

In the I-L characteristics assumed in the present embodiment, as shown in FIG. 2A, the optical output increases with an increase in the injection current, and when the injection current exceeds the threshold current Iₜₕ, the optical output increases rapidly. Further, when the injection current increases, the optical output decreases.

FIGS. 2B to 2E show an example of a mode in which the threshold current Iₜₕ is acquired on the basis of the I-L characteristics in the present embodiment. In the present embodiment, in the I-L characteristic, the threshold current Iₜₕ is obtained by sequentially shifting (incrementing) the measurement point (data) in an increasing direction of the injection current.

In the drawing, black circles indicate the nth measurement point. An arrow in the drawing is an approximate straight line obtained by linear approximation using 2k+1 pieces of measurement data from the n−k-th to the n+k-th in the n-th measurement point, and a tip shows an intersection point (X-intercept) with the X-axis.

First, when the measurement point shifts in a current region sufficiently lower than the threshold current Iₜₕ, the slope of the approximate straight line is almost zero, and the X-intercept is also near the origin (FIG. 2B).

Next, when the measurement point shifts in the increasing direction of the injection current in a current region lower than the threshold current Iₜₕ, the X-intercept of the approximate straight line becomes a positive value, and is positioned between the origin and the threshold current Iₜₕ (FIG. 2C).

Next, when the measurement point shifts in a region in which the I-L characteristics linearly change in a current region in which the measurement point is higher than the threshold current Iₜₕ, the X-intercept of the approximate straight line shows the threshold current Iₜₕ (FIG. 2D).

Next, when the measurement point shifts in a region in which linearity of I-L characteristics is maintained in a current region higher than the threshold current Iₜₕ, the X-intercept of the approximate straight line similarly indicates the threshold current Iₜₕ (FIG. 2E).

Finally, when the measurement point shifts in a region in which the increase rate of the optical output, that is, the slope of the I-L characteristics decreases in a higher injection current region, the X-intercept of the approximate straight line shows a value lower than the threshold current Iₜₕ (FIG. 2F).

In this way, when the measurement points are sequentially shifted (incremented) in the increasing direction of the injection current in the I-L characteristics, the intersection point (X-intercept) of the approximate straight line and the X-axis at the measurement points increases in the X-axis (injection current) direction, reaches the threshold current Iₜₕ, shows the local maximum values, and then decreases.

Therefore, the threshold current Iₜₕ can be acquired by sequentially shifting (incrementing) the measurement points in the increasing direction of the injection current in the I-L characteristics and extracting the local maximum values of the X-intercept.

Here, when the local maximum values of the plurality of X-intercepts are extracted, the local maximum values of the X-intercepts acquired first, that is, a minimum value among the local maximum values of the plurality of X-intercepts, may be set to the threshold current Iₜₕ (to be described later).

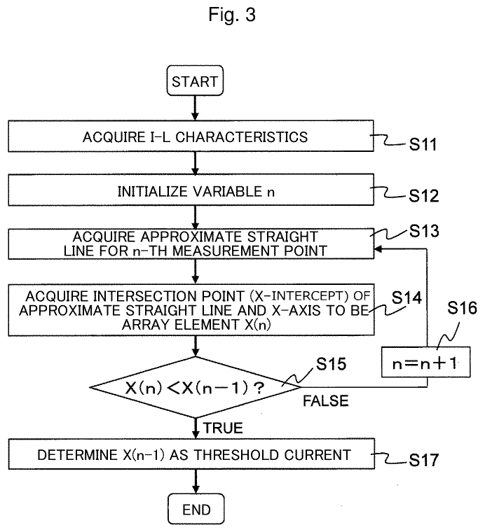

FIG. 3 shows a flowchart of an example of the semiconductor laser evaluation method according to the present embodiment.

In the measurement of the I-L characteristics, the drive unit 11 supplies an injection current to the semiconductor laser 1, and the detection unit 12 detects the optical output of the semiconductor laser 1. A relation between the injection current and the optical output that are output from each of the drive unit 11 and the detection unit 12 is measured as I-L characteristics.

This measured I-L characteristics are stored in the storage unit 14.

First, the calculation unit 13 acquires I-L characteristics from the storage unit 14 (step S11). Alternatively, the measured I-L characteristics may be directly acquired by the calculation unit 13.

Next, a variable (index) n of the I-L characteristic data is initialized by an index of an array initial value (step S12). Here, the variable (index) n of the I-L characteristic data is the number (numerical value indicating the order) of the I-L characteristic data. The index of the array initial value is the number of the first data of the I-L characteristic data used for threshold current evaluation. For example, when the index of the initial array value is 1, the initial array value is initialized to n=1.

Next, in the I-L characteristic, for the n-th measurement point, an approximate straight line is acquired by linear approximation of 2k+1 pieces of measurement data from the n−k-th to the n+k-th (step S13). Hereinafter, k is referred to as an “averaging parameter”. Here, a least square method or the like is used for linear approximation.

Next, an intersection point (X-intercept) between the approximate straight line and the X-axis is obtained, and defined as an array element X(n) (step S14).

Next, an X-intercept (X(n)) at the n-th measurement point is compared with an X-intercept (X(n−1)) at the n−1-th measurement point before the measurement point (step S15).

When X(n) is X(n−1) or more, next data (n+1-th data) is selected (step S16), and similar steps are performed (steps S13 to S15).

On the other hand, when X(n) indicates a value lower than X(n−1), X(n−1) is determined as a threshold current, and evaluation is finished (step S17). Thus, the local maximum value of the intercept is determined as the threshold current.

Here, although an example in which X(n−1) is determined as the threshold current when X(n) shows a value lower than X(n−1) is shown, the embodiment is not limited thereto. When X(n) shows a value lower than a plurality of pieces of data measured before X(n), any of the plurality of pieces of data may be determined as a threshold current.

For example, when X(n) shows a value lower than X(n−1) and X(n−2), that is, when X(n)<X(n−1) and X(n)<X(n−2), the X(n−2) which becomes the local maximum value if X(n−1)<X(n−2) may be determined as the threshold current.

Thus, the influence of an experimental error such as noise is suppressed, and an accurate threshold current can be acquired.

In the present embodiment, although an example in which n is sequentially increased is shown, n may be sequentially decreased. In this case, for example, X(n) and X(n+1) are compared, and when X(n)<X(n+1), X(n+1) is determined as a threshold current. In this way, the local maximum values of X(n) may be obtained by changing (shifting) n.

Further, in the semiconductor laser evaluation method according to the present embodiment, in a case where the local maximum values of a plurality of X-intercepts are acquired when n is sequentially increased, the local maximum value of the X-intercept acquired first is set as the threshold current Iₜₕ. In the case where the local maximum values of the plurality of X-intercepts are acquired when the n is sequentially reduced, the local maximum value of the X-intercept acquired last is set as the threshold current Iₜₕ. That is, the minimum value among the local maximum values of the plurality of X-intercepts is determined as the threshold current Iₜₕ.

In this way, in the semiconductor laser evaluation method according to the present embodiment, in I-L characteristics, the minimum value of the local maximum values of the intersection points between the approximate straight line and the X-axis obtained by linear approximation for predetermined measurement point is determined as the threshold current of the semiconductor laser.

### Effect

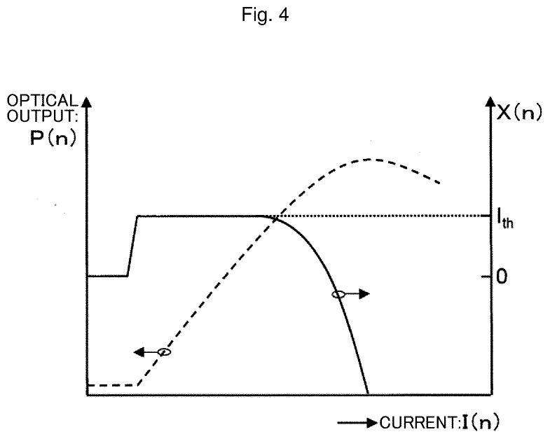

The effects of the semiconductor laser evaluation method according to the present embodiment will be explained with reference to FIGS. 4 to 8B.

FIG. 4 shows the I-L characteristic (dotted line in the drawing) and the change of X(n) as an X-intercept (solid line in the drawing) in the present embodiment.

X(n) is substantially zero in the region in which the injection current I(n) is low, and shows a substantially constant value after the injection current I(n) increases abruptly. Further, when the injection current I(n) increases, X(n) decreases and indicates a negative value.

From the change of X(n), X(n) which becomes the local maximum value is determined as the threshold current Iₜₕ.

Next, the semiconductor laser evaluation method according to the present embodiment is compared with the conventional method 1.

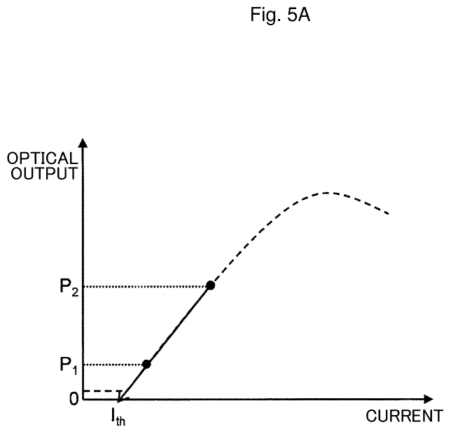

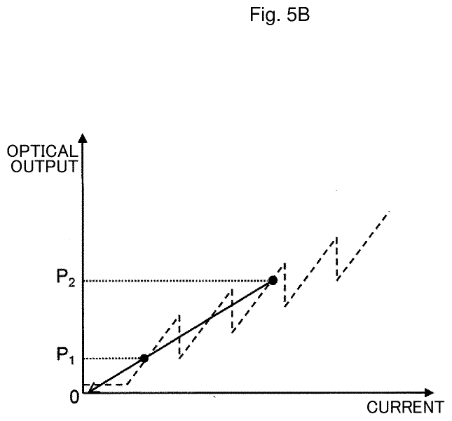

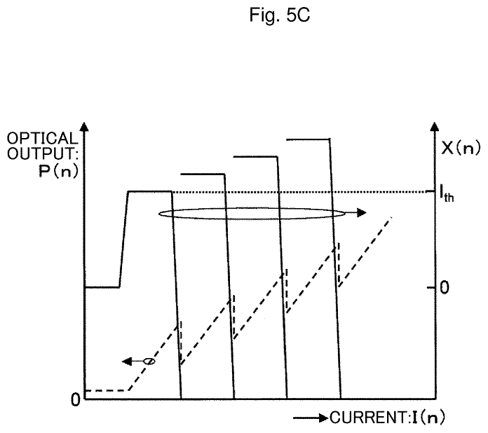

In the conventional method 1, as shown in FIG. 5A, a straight line that connects two points measured in a linear region after laser oscillation in I-L characteristics (dotted line in the drawing) is extended (solid line arrow in the drawing) to determine the threshold current Iₜₕ.

However, as shown in FIG. 5B, when a plurality of bends (kinks) occur in I-L characteristics (dotted lines in the drawing), even if a straight line that connects two measured points is extended (solid line arrows in the drawing), the threshold current cannot be evaluated accurately.

On the other hand, according to the semiconductor laser evaluation method according to the present embodiment, as shown in FIG. 5C, X(n) (solid line in the drawing) shows a plurality of local maximum values corresponding to each of a plurality of kinks in the I-L characteristic (dotted line in the drawing). Among these local maximum values, X(n) corresponding to the local maximum value acquired first, that is, the minimum X(n) among the plurality of local maximum values is defined as the threshold current Iₜₕ. Thus, the threshold current can be accurately evaluated.

In the conventional method 1, there is a case where the threshold current cannot be evaluated with the same parameter for all of a plurality of semiconductor lasers having different I-L characteristics. For example, when the threshold current is evaluated from between predetermined two points, there is a case where measurement data at two points may not be acquired for all I-L characteristics of a plurality of semiconductor lasers.

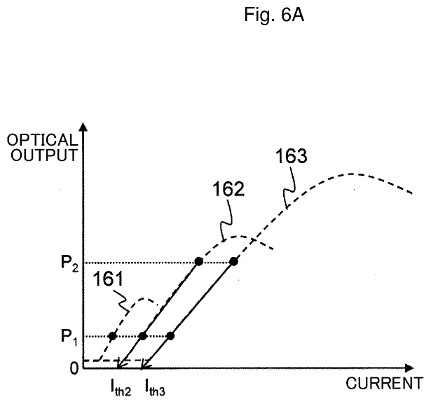

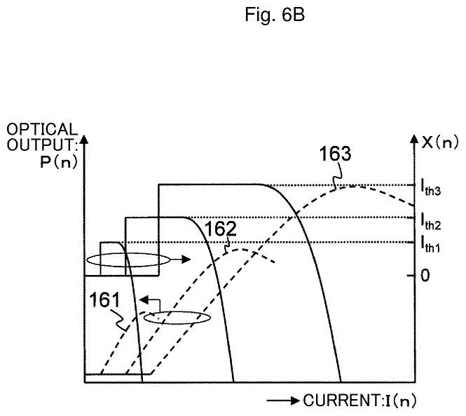

For example, in the case shown in FIG. 6A, since measurement data of two points corresponding to the optical outputs P1 and P2 can be acquired in I-L characteristics (dotted lines in the drawing) 162 and 163, a straight line that connects these two points is extended (solid line arrow in the drawing), and the threshold current can be accurately evaluated.

However, in the I-L characteristic (dotted line in the drawing) 161, measurement data corresponding to the optical output P2 cannot be acquired, and measurement data of two points cannot be acquired. As a result, the threshold current cannot be accurately evaluated in all of the plurality of semiconductor lasers.

On the other hand, according to the semiconductor laser evaluation method according to the present embodiment, as shown in FIG. 6B, the local maximum value of X(n) (solid line in the drawing) can be acquired for each of laser I-L characteristics (dotted line in the drawing) 161, 162, and 163 of a plurality of semiconductors. Therefore, since each local maximum value of X(n) can be acquired as threshold currents Iₜₕ₁, Iₜₕ₂, and Iₜₕ₃ of each of the plurality of semiconductor lasers, the threshold current can be accurately evaluated.

Next, the semiconductor laser evaluation method according to the present embodiment is compared with the conventional method 4.

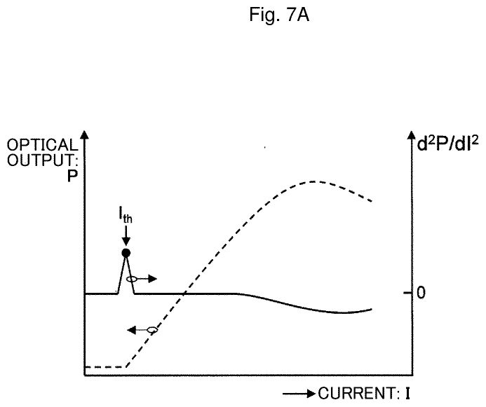

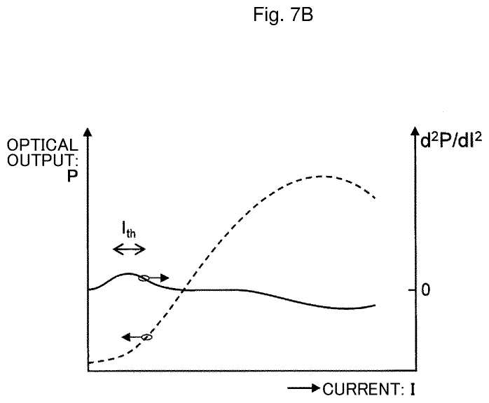

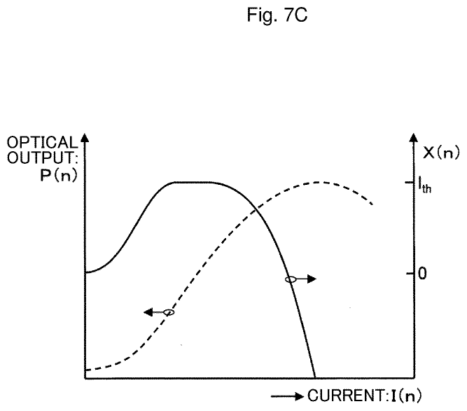

In the conventional method 4, as shown in FIG. 7A, a threshold current Iₜₕ is determined from a peak value of a second-order differential coefficient d²L/dI² (solid line in the drawing) in I-L characteristics (dotted line in the drawing). Therefore, when the I-L characteristic sharply changes in the vicinity of the threshold current, since a steep peak of d²L/dI² can be obtained, the threshold current Iₜₕ can be easily determined.

However, as shown in FIG. 7B, when the I-L characteristic (dotted line in the drawing) changes gently near the threshold current, the threshold current Iₜₕ cannot be determined easily because a steep peak of d²L/dI² (solid line in the drawing) cannot be obtained.

On the other hand, according to the semiconductor laser evaluation method according to the present embodiment, since X(n) (solid line in the drawing) clearly shows the local maximum value as shown in FIG. 7C, the accurate threshold current Iₜₕ can be easily determined.

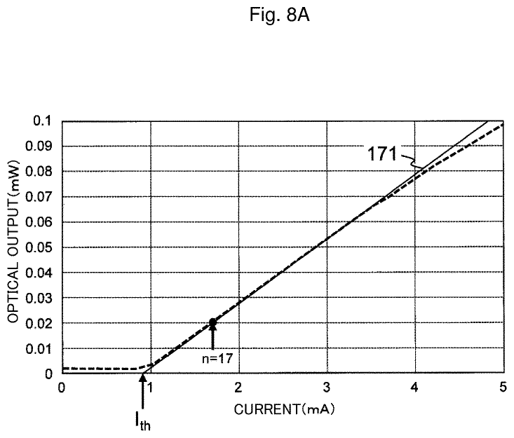

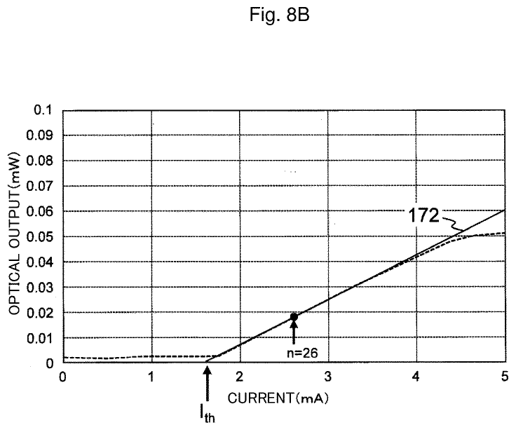

Subsequently, Experimental Results Obtained by the semiconductor laser evaluation method according to the present embodiment will be explained with reference to FIGS. 8A and 8B.

A semiconductor laser a and a semiconductor laser b having different I-L characteristics are used for the semiconductor laser to be evaluated. FIGS. 8A and 8B each show experimental results (I-L characteristics) for the semiconductor lasers a and b. Here, experiments (evaluation) were performed with the averaging parameter k set to 5.

As a result of evaluation of the I-L characteristic (dotted line in the drawing) of the semiconductor laser (a), X(n) shows a local maximum value at n=17 (equivalent to 1.7 mA of injection current), and a threshold current Iₜₕ is 0.88 mA as shown in FIG. 8A. The approximate straight line at this time is indicated by a solid line 171 in the drawing.

As a result of evaluation of the I-L characteristic (dotted line in the drawing) of the semiconductor laser b, X(n) shows a local maximum value and a threshold current Iₜₕ is 1.60 mA in n=26 (equivalent to implantation current: 2.6 mA) as shown in FIG. 8B. The approximate straight line at this time is indicated by a solid line 172 in the drawing.

### Second Embodiment

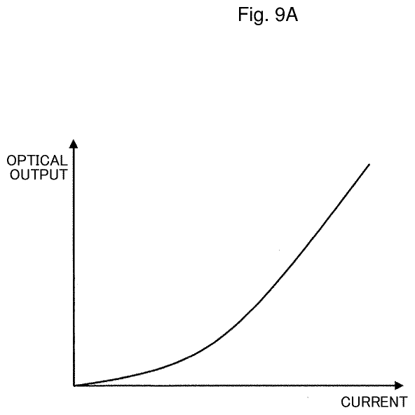

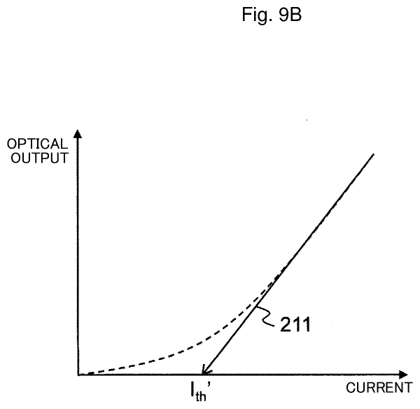

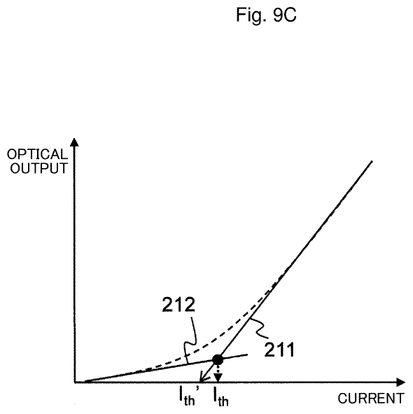

A semiconductor laser evaluation device, method, and program according to a second embodiment of the present invention will be described with reference to FIGS. 9A to 11B. The configuration of the semiconductor laser evaluation device according to the present embodiment is the same as that of the first embodiment.

### Semiconductor Laser Evaluation Method

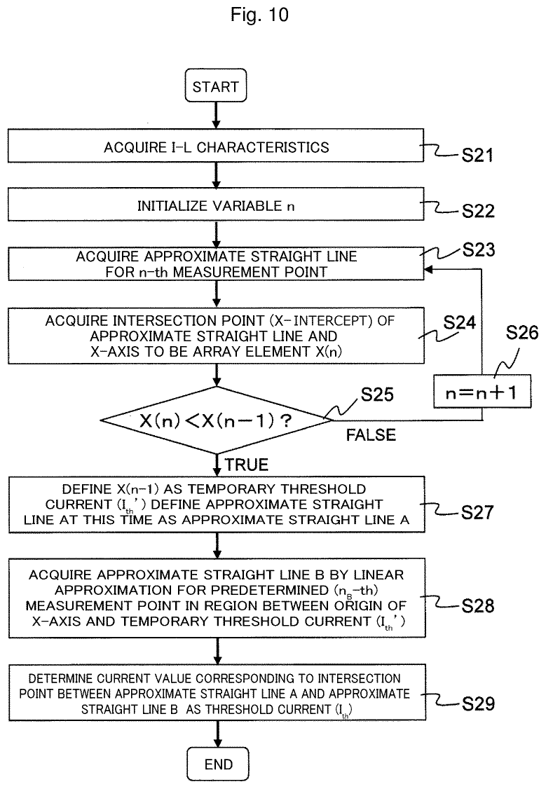

FIGS. 9A to 9C show the concept of the semiconductor laser evaluation method according to the present embodiment. FIG. 10 shows a flowchart of an example of the semiconductor laser evaluation method according to the present embodiment.

In the present embodiment, it is assumed that the change of the optical output near the threshold value in the I-L characteristic is gentle as shown in FIG. 9A.

First, as in the first embodiment, the local maximum value of X(n) is acquired from the intersection point (X-intercept) between the approximate straight line and the X-axis by linear approximation in the I-L characteristic (dotted line in the drawing). The local maximum value of X(n) is defined as a temporary threshold current Iₜₕ′ (FIG. 9B). The approximate straight line at this time (hereinafter, referred to as “approximate straight line A”) is designated as a solid line 211 in FIG. 9B.

Specifically, in the I-L characteristics, the approximate straight line is obtained by linear approximation of 2k_{A}+1 pieces of measurement data from the n−k_{A}-th to the n+k_{A}-th with respect to the n-th measurement point. The local maximum value of X(n), which is the intersection point (X-intercept) between the approximate straight line and the X-axis is referred to as a temporary threshold current Iₜₕ′. The approximate straight line at this time is defined as an approximate straight line A (steps S21 to S27).

Next, for a predetermined measurement point (an np-th measurement point) in a region from the origin of the I-L characteristic to the Iₜₕ′, an approximate straight line (hereinafter referred to as “approximate straight line B”) is obtained by linear approximation. A solid line 212 in the drawing is determined (FIG. 9C, step S28). The approximate straight line Bis obtained by linear approximation of 2kg_{B}+1 pieces of measurement data from the n_{B}−k_{B}-th to the n_{B}+k_{B}-th with respect to the n_{B}-th measurement point.

Here, an intermediate point (n′/2nd measurement point) between the origin and the measurement point n′ corresponding to Iₜₕ′ is used for a predetermined measurement point (n_{B}-th measurement point). Further, n′/3rd and n′/4th measurement points may be used in addition to the n′/2nd measurement point. Further, a measurement point (n′−k₀-th measurement point) of before several points of the measurement point corresponding to Iₜₕ′ may be used.

Finally, a current value corresponding to an intersection point (black circle in the drawing) of the approximate straight line Q and the approximate straight line B is determined as a threshold current Iₜₕ (FIG. 9C, step S29).

Further, in the semiconductor laser evaluation method according to the present embodiment, when the local maximum values of a plurality of X-intercepts (X(n)) are acquired, the minimum value among the local maximum values of the plurality of X(n) is regarded as a temporary threshold current Iₜₕ′.

### Effect

In the I-L characteristics of the semiconductor laser, since spontaneous emission light from the semiconductor laser is very strong, there is a case in which the change of the optical output near the threshold value is gentle. Further, light may be detected even in a current region below the threshold value due to noise or dark current in the light receiver of the measuring system.

When the threshold current is evaluated by the semiconductor laser evaluation method according to the conventional method and the first embodiment, a value lower than the actual threshold current corresponding to the change in the I-L characteristics is determined as the threshold current. As a result, the threshold current cannot be accurately evaluated.

According to the semiconductor laser evaluation method according to the present embodiment, the threshold current can be evaluated accurately in accordance with the change in I-L characteristics, as described above.

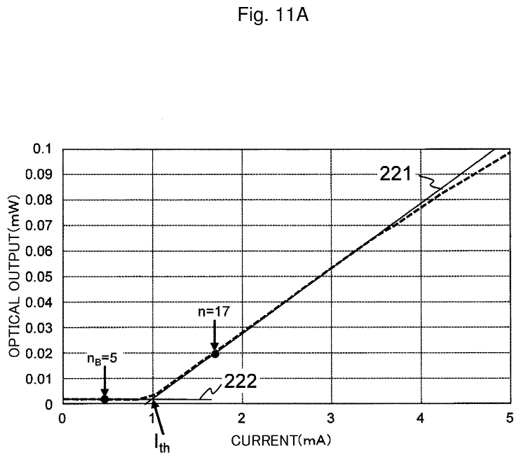

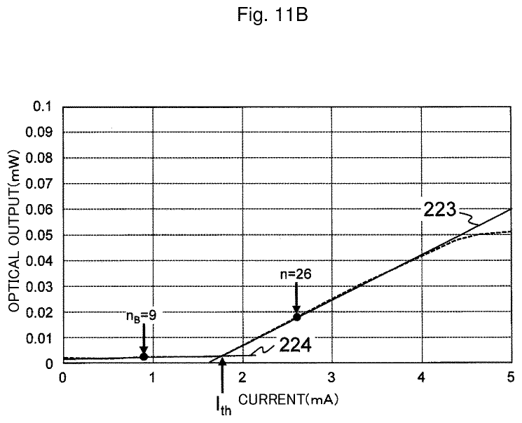

Subsequently, experimental results obtained by the evaluation method according to the present embodiment will be described with reference to FIGS. 11A and 11B.

As the semiconductor laser to be evaluated, a semiconductor laser a and a semiconductor laser b having different I-L characteristics were used as in the first embodiment. FIGS. 11A and 11B each show experimental results for the semiconductor laser a and the semiconductor laser b.

As a result of evaluation of the I-L characteristics (dotted line in the drawing) of the semiconductor laser a with the averaging parameter K_{A} as 5, X(n) shows a local maximum value at n=17 (corresponding to 1.7 mA of injection current) and a temporary threshold current Iₜₕ′ is 0.88 mA as shown in FIG. 11A. The approximate straight line A at this time is indicated by a solid line 221 in the drawing.

Further, an approximate straight line B (solid line 222 in the drawing) was obtained by linearly approximating the intermediate measurement point (n_{B}-th measurement point, n_{B}=5) between the origin and the measurement point corresponding to the temporary threshold current Iₜₕ′ with k_{B}=5.

From the intersection point between the approximate straight line A and the approximate straight line B, the threshold current Iₜₕ of the semiconductor laser a was obtained at 0.98 mA.

Next, as a result of evaluation of the I-L characteristic s (dotted line in the drawing) of the semiconductor laser b with the averaging parameter k_{A} as 5, and as shown in FIG. 11B, X(n) showed a local maximum value at m=26 (corresponding to 2.6 mA of injection current), and a temporary threshold current Iₜₕ′ was obtained at 1.60 mA. The approximate straight line A at this time is indicated by a solid line 223 in the drawing.

Further, an approximate straight line B (solid line 224 in the drawing) was obtained by linearly approximating the intermediate measurement point (n_{B}-th measurement point, n_{B}=9) between the origin and the measurement point corresponding to the temporary threshold current Iₜₕ′ with K_{B}=5.

From the intersection point between the approximate straight line A and the approximate straight line B, the threshold current Iₜₕ of the semiconductor laser B was obtained at 1.74 mA.

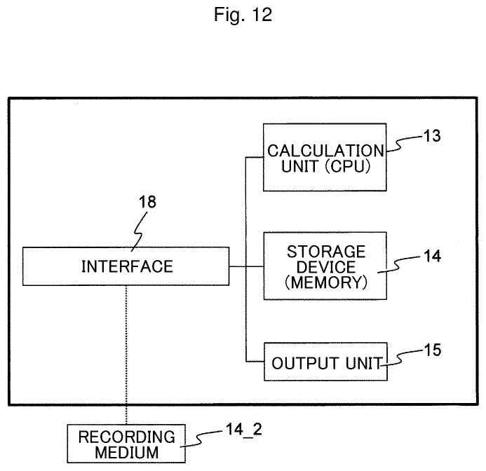

FIG. 12 shows a configuration example of a computer for executing the semiconductor laser evaluation method according to the embodiment of the present invention. This semiconductor laser evaluation method can be realized by a computer equipped with a central processing unit (CPU) in the calculation unit 13, a storage device (storage unit) 14, and an interface device 18, and a program that controls these hardware resources. The interface device 18 is connected to the drive unit 11, the detection unit 12, and the output unit 15. The CPU executes processing described in the embodiments of the present invention in accordance with the semiconductor laser evaluation program stored in the storage device 14. In this way, the semiconductor laser evaluation program executes the semiconductor laser evaluation method according to the present embodiment.

The semiconductor laser evaluation device 10 according to the embodiment of the present invention may include a computer inside the device, or may realize at least part of the functions of the computer, using an external computer. Further, the storage unit 14 may also use a storage medium 14_2 outside the device, and may read and execute a semiconductor laser evaluation program stored in the storage medium 14_2. The storage medium 14_2 includes various magnetic recording media, magneto-optical recording media, a CD-ROM, a CD-R, and various memories. Furthermore, the semiconductor laser evaluation program may be supplied to the computer via a communication line such as Internet.

In the embodiment of the present invention, although an example of an algorithm, a parameter, a structure of each component, and the like in the semiconductor laser evaluation method, device, and program has been shown, the present invention is not limited thereto. Any modifications can be made as long as it exhibits the functions and effects of the semiconductor laser evaluation method, device, and program.

### INDUSTRIAL APPLICABILITY

The present invention relates to a semiconductor laser evaluation method, device, and program for determining the threshold current of a semiconductor laser, and can be applied to improving the characteristics of the semiconductor laser.

### REFERENCE SIGNS LIST

1 Semiconductor laser
10 Semiconductor laser evaluation device
11 Drive unit
12 Detection unit
13 Calculation unit

1. A semiconductor laser evaluation method, the method comprising:
in a current-light output characteristic representing a relationship between an injection current of a semiconductor laser and an optical output of the semiconductor laser, with the injection current on an X-axis and the optical output on a Y-axis, obtaining a plurality of intersection points between a plurality of approximate straight lines acquired by a linear approximation for each of a plurality of measurement points and the X-axis; and determining a minimum value of local maximum values of the plurality of intersection points to variation of the injection current, as a threshold current of the semiconductor laser.

2. The semiconductor laser evaluation method according to claim 1, further comprising:
acquiring the current-light output characteristic from an injection current of the semiconductor laser and an optical output of the semiconductor laser;
wherein obtaining the plurality of intersection points includes:
shifting a predetermined measurement point among the plurality of measurement points to acquire the plurality of approximate straight lines by a linear approximation for the predetermined measurement point in the current-light output characteristic; and
obtaining an intersection point between the plurality of approximate straight lines and the X-axis; and
determining a minimum value of local maximum values of the plurality of intersection points, as a threshold current of the semiconductor laser, includes:
obtaining the local maximum values of the plurality of intersection points.

3. A semiconductor laser evaluation method, the method comprising: in a current-light output characteristic representing a relationship between an injection current of a semiconductor laser and an optical output of the semiconductor laser, with the injection current on an X-axis and the optical output on a Y-axis, obtaining a plurality of first intersection points between a plurality of first approximate straight lines acquired by a linear approximation for each of a plurality of first measurement points and the X-axis; obtaining local maximum values of the plurality of first intersection points to variation of the injection current; acquiring a second approximate straight line by a second linear approximation with respect to a second measurement point between an origin of the X-axis and a minimum value of the local maximum values; and determining a current value corresponding to an intersection point between the first approximate straight line and the second approximate straight line, as a threshold current of the semiconductor laser.

4. The semiconductor laser evaluation method according to claim 3, further comprising:
acquiring the current-light output characteristic from an injection current of the semiconductor laser and an optical output of the semiconductor laser;
wherein obtaining the plurality of first intersection points includes:
shifting a first predetermined measurement point among the plurality of first measurement points to acquire that first approximate straight line by a linear approximation for the first predetermined measurement point in the current-light output characteristic; and
obtaining an intersection point between the first approximate straight line and the X-axis; and
obtaining local maximum values of the plurality of first intersection points includes:
shifting the first predetermined measurement point among the plurality of first measurement points to obtain the local maximum values of the intersection points; and
determining a current value corresponding to an intersection point between the first approximate straight line and the second approximate straight line, as a threshold current of the semiconductor laser, includes:
acquiring the second approximate straight line by the linear approximation for a second predetermined measurement point in a region between an origin of the X-axis and a minimum value of the local maximum values.

5. A semiconductor laser evaluation device comprising:
a drive circuit configured to supply an injection current to a semiconductor laser;
a detection circuit configured to detect an optical output of the semiconductor laser; and
calculation circuit configured to obtain, in a current-light output characteristic representing a relationship between the injection current of the semiconductor laser and the optical output of the semiconductor laser, with the injection current on an X-axis and the optical output on a Y-axis, an a plurality of intersection points between a plurality of approximate straight lines acquired by a linear approximation for a each of a plurality of measurement points and the X-axis, and determine a minimum value of local maximum values of the plurality of intersection points to variation of the injection current, as a threshold current of the semiconductor laser.

6. A semiconductor laser evaluation device comprising:
a drive circuit configured to supply an injection current to a semiconductor laser;
a detection circuit configured to detect an optical output of the semiconductor laser; and
a calculation circuit configured to obtain, in a current-light output characteristic representing a relationship between the injection current of the semiconductor laser and the optical output of the semiconductor laser, with the injection current on an X-axis and the optical output on a Y-axis, a plurality of first intersection points between a plurality of first approximate straight lines acquired by a linear approximation for each of a plurality of first measurement points and the X-axis, obtain local maximum values of the plurality of first intersection points to variation of the injection current, a second approximate straight line by a linear approximation with respect to a second measurement point between an origin of the X-axis and a minimum value of the local maximum values, and determine a current value corresponding to an intersection point between the first approximate straight line and the second approximate straight line, as a threshold current of the semiconductor laser.

7. A non-transitory computer-readable recording medium which stores a semiconductor laser evaluation program for causing a computer which evaluates a threshold current of a semiconductor laser to perform the method according to claim 1.

8. A non-transitory computer-readable recording medium which stores a semiconductor laser evaluation program for causing a computer which evaluates a threshold current of a semiconductor laser to perform the method according to claim 3.
